(19) United States
(12) Patent Application Publication
(10) Pub. No.: US 2018/0366455 A1
(43) Pub. Date: Dec. 20, 2018

(54) Method for Producing an Electronic Circuit Device and Electronic Circuit Device

(71) Applicant: Robert Bosch GmbH, Stuttgart (DE)

(72) Inventors: Konstantin Spanos, Wildberg (DE); Walter Daves, Stuttgart-Feuerbach (DE); Stephan Schwaiger, Leonberg (DE)

(21) Appl. No.: 15/570,648

(22) PCT Filed: Mar. 8, 2016
(86) PCT No.: PCT/EP2016/054884

§ 371 Date: Oct. 30, 2017

(30) Foreign Application Priority Data
May 4, 2015 (DE) 10 2015 208 150.8

(51) Int. Cl. H01L 25/16; H01L 25/07; H01L 23/00; H01L 23/498; H01L 49/02; H01L 29/20; H01L 29/861; H01L 29/778; H01L 21/48; H01L 25/00; H01L 29/66

(52) U.S. Cl. CPC H01L 25/16; H02M 7/537; H01L 24/48; H01L 23/49844; H01L 28/40; H01L 29/2003; H01L 29/861; H01L 29/7787; H01L 21/4853; H01L 25/50; H01L 29/6609; H01L 29/66462; H01L 2224/4813; H01L 2224/48227; H01L 2924/19041; H01L 2924/14252; H01L 2924/19105; H01L 2924/19104; H01L 25/072

(57) ABSTRACT

A method for producing an electronic circuit device includes a step of providing a substrate and a step of processing a III-V-connection semiconductor circuit on a substrate top side of the substrate. The III-V-connection semiconductor circuit has at least one III-V-connection semiconductor component, a second III-V-connection semiconductor component, and an electrical conductor, which electrically conductively connects the first III-V connection semiconductor component and the second III-V connection semiconductor component. In an arranging step, a metal layer or a metallized interconnect device is arranged on a rear side of the substrate, opposite the substrate top side, as an electrical contact surface for refeeding a current for a power electronic circuit.

### PRIOR ART

The present invention relates to a method for producing an electronic circuit device and to a corresponding electronic circuit device.

In order to fabricate cost-effective HEMT components (HEMT=High-electron-mobility transistor) made from wide band gap semiconductors, silicon is often used as a separate substrate and the active layer is deposited thereon. By way of example, an active GaN/AlGaN heterostructure can be deposited on the front side of a silicon substrate by MOCVD methods (MOCVD=Metal-organic chemical vapor deposition). The transistors fabricated thereon are processed in subsequent steps on the front side and are finally processed to form individual transistors. Afterward, the transistors are joined together with the necessary passive components, e.g. coils, capacitors, resistors, to form an electrical circuit.

### DISCLOSURE OF THE INVENTION

Against this background, the approach presented here presents a method for producing an electronic circuit device and an electronic circuit device as claimed in the main claims. Advantageous configurations are evident from the respective dependent claims and the description below.

Components composed of semiconductor materials of the III-V material system, e.g. composed of GaN, AlN or AlGaN, offer the potential to serve as an electronic switch for power electronics on a large industrial scale. Heterostructures composed of AlGaN/GaN for example form at their interface a two-dimensional electron gas distinguished by a high mobility (typically 2000 cm²/Vs) and hence a low sheet resistance. Through the combination of the low sheet resistance with the high breakdown strength of the systems, it is possible to produce transistors having a low power loss and at the same time a high blocking capability which are far superior to the silicon-based systems in terms of the physical limits.

Furthermore, in contrast to the conventional Si— or SiC-based power transistors, these transistors are implemented laterally in principle, that is to say that all the transistor terminals are situated on the front side. This property can be utilized very advantageously in order to increase the integration density of the power electronic circuits.

By processing III-V compound semiconductor components and an electrical conductor on a substrate, it is possible to increase the integration density of power semiconductor circuits on the basis of the components. By way of example, in this case, the III-V compound semiconductor components can be used as lateral switching transistors of a commutation cell of a III-V power switch.

In one development of the approach presented here, in the case of a correspondingly embodied semiconductor circuit, the current can be fed back on the semiconductor rear side. On the other hand, the rear side of a substrate used for the circuit, e.g. of a silicon substrate, on the front side of which is situated the semiconductor circuit, e.g. a bridge or inverter circuit, can be used for contact pads and also for integrated passive components, in particular the link capacitor and/or parts of the gate driving electronics.

Advantageously, the available chip area can thus be maximally utilized and wafer costs can be saved. Costly bonding and soldering connections can also be reduced since connections between the individual components can he realized at the wafer level. In accordance with the approach presented here, the short distance between components such as link capacitor and active transistors can be reduced and a low-inductance circuit can thus be realized. In conjunction with available wide band gap semiconductors this enables extremely high switching speeds and hence minimal switching losses with extremely small switching overvoltages and reduced EMC interference emission (EMC=electromagnetic compatibility). Extremely high switching frequencies are made possible as a result.

As a further advantage, the front side of the circuit can be utilized for heat dissipation purposes, said front side offering a lower thermal resistance with respect to the heat sink than the rear side. The construction of the circuit device can be fashioned with particularly low interference from an EMC standpoint on account of the transfer of the dynamic node to the semiconductor top side and the high symmetry. Since the functional insulation is implemented separately in the concept presented here, the proposed construction design makes it possible to monolithically integrate EMC filter components, e.g. RC snubbers or Y capacitors for terminals.

A method for producing an electronic circuit device is presented, wherein the method comprises the following steps:

providing a substrate; and

processing a III-V compound semiconductor circuit, on a substrate top side of the substrate, wherein the III-V compound semiconductor circuit comprises at least one first III-V compound semiconductor component, a second III-V compound semiconductor component and an electrical conductor, which electrically conductively connects the first III-V compound semiconductor component and the second III-V compound semiconductor component; and

arranging a metal layer or a metallized circuit carrier on a rear side of the substrate, said rear side being situated opposite the substrate top side, as an electrical contact pad for feeding back a current for a power electronic circuit.

The method can be implemented in a fully or partly automated manufacturing installation. The electronic circuit device can be a power electronic circuit or a part of a power electronic circuit which can be used for example in a rotational speed-variable motor controller. The substrate can serve as a carrier for the III-V compound semiconductor circuit and be present for example in a the form of a silicon wafer. Processing can be understood firstly to mean applying, in terms of process engineering, the semiconductor circuit materials—that is to say the first III-V compound semiconductor component, the second III-V compound semiconductor component and the electrical conductor—to the substrate surface, for example using a vapor deposition method. It can be understood secondly to mean selective removal of specific materials or selective insulation in specific regions.

A power electronic circuit can be for example a half-bridge, a full-bridge or an inverter circuit. The metallized circuit carrier can comprise a metallization or the metal layer. In this regard, an electrical contact pad and/or an electrical line to that of the III-V compound semiconductor circuit can readily be provided. The electrical contact pad can be used for feeding back the current in the power electronic circuit. The metallized circuit carrier can be embodied in a continuous or structured fashion. Furthermore, the metal layer rear side of the substrate formed by the metallized circuit carrier can be electrically connected to the III-V compound semiconductor components with the aid of through contacts. By using the rear side of the substrate as a current-carrying part of the power electronic circuit, a low-inductance construction is made possible.

One main advantage of the approach described is that firstly all the III-V compound semiconductor components are produced by the semiconductor materials being applied in terms of process engineering. In the subsequent step, the III-V compound semiconductor components can be insulated from one another and can finally be electrically connected to one another at the required terminals at the wafer level.

Consequently, the approach described enables a combination of a III-V compound semiconductor circuit at the wafer level with further elements, such as a current-carrying rear side, an integration of passive components, such as a capacitor, or the integration of parts of a driver circuit.

The first III-V compound semiconductor component and the second III-V compound semiconductor component should be understood to mean electrical components which comprise compounds of materials of chemical main group III and chemical main group V. The first III-V compound semiconductor component and the second III-V compound semiconductor component can in this case have an identical or different material composition. In the combination of the materials of main groups III and V, the electrical conductivity of semiconductors is imparted to the components. For the purpose of electrically conductively connecting the III-V compound semiconductor components, it is possible to process the electrical conductor between side surfaces of the III-V compound semiconductor components on the substrate surface. The electrical conductor can be understood as an electrical line or conductor track led between terminals of the components.

The step of processing can comprise a step of whole-area deposition, in which the III-V compound semiconductor components are deposited over the whole area as a composite element. Consequently, the two components initially do not exist as individual independent components, but rather as a composite. Furthermore, the step of processing can comprise a step of processing the composite element in order to obtain the first III-V compound semiconductor component and the second III-V compound semiconductor component as two independent III-V compound semiconductor components. Finally, the step of processing can comprise a step of metalizing, in which the electrical conductor can be produced. In accordance with one embodiment, in the step of processing, the first. III-V compound semiconductor component and the second III-V compound semiconductor component can be processed on a III-V compound semiconductor layer. In this case, the two components can be intermeshed in one another. In the step of processing, the electrical conductor can be positioned and structured on a III-V compound semiconductor material, for example on the III-V compound semiconductor layer mentioned.

In accordance with one embodiment of the method, in the step of processing, the first III-V compound semiconductor component, the second III-V compound semiconductor component and the electrical conductor can be produced using a chemical vapor deposition method, for example a metal-organic chemical vapor deposition method. Chemical vapor deposition affords the advantage of a particularly uniform and exact shaping of the individual component parts of the III-V compound semiconductor circuit on the substrate surface. Manufacturing tolerances can be reduced to a minimum.

By way of example, in the step of processing, a III-V compound semiconductor circuit can be processed for example as a half- or full-bridge, as an inverter circuit or as further power electronic circuits consisting of at least two elements. The circuits can be realized particularly cost-effectively with the method presented.

In accordance with one embodiment of the method, in the step of processing, the first III-V compound semiconductor component can be processed as a switch of the III-V compound semiconductor circuit and the second III-V compound semiconductor component can be processed as a diode of the III-V compound semiconductor circuit.

Furthermore, the method can comprise a step of providing a passive circuit element for the electronic circuit device. In this case, a terminal of the passive circuit element can be electrically conductively connected to at least one of the III-V compound semiconductor components. By way of example, a capacitor can be integrated as a passive circuit element, for example on the rear side of the substrate. With the integration of the passive circuit element, the commutation processes required for the circuit function can be made possible in the electronic circuit device.

In accordance with one embodiment, in the step of providing the passive circuit element, the passive circuit element can be produced at the further substrate surface. After production, the substrate on which the passive components are situated can be electrically and mechanically connected to the substrate on which the III-V compound semiconductor components are situated. Besides the capability of using a cost-effective series product as the passive circuit element, the advantage of this embodiment consists in a capability of electrically linking the passive circuit element to the III-V compound semiconductor circuit in a manner that is simple to realize and cost-effective.

Alternatively, in the step of providing the passive circuit element, the passive circuit element can be arranged at a surface of the (partly) metallized circuit carrier facing away from the further substrate surface of the substrate. In this embodiment, a passive circuit element of any desired size and shape can advantageous be used.

Furthermore, in accordance with the approach presented here, there is the possibility, in the step of providing the substrate, of the substrate being provided with a least one plated-through hole for contacting the III-V compound semiconductor circuit. A low-inductance circuit construction can be realized with this embodiment.

Furthermore, an electronic circuit device comprising the following features is presented:

a substrate; and

a III-V compound semiconductor circuit arranged on a substrate top side of the substrate, wherein the III-V compound semiconductor circuit comprises at least one first III-V compound semiconductor component, a second III-V compound semiconductor component and an electrical conductor, which electrically conductively connects the first III-V compound semiconductor component and the second III-V compound semiconductor component.

The electronic circuit device can comprise a metal layer and additionally or alternatively a metallized circuit carrier, which can be arranged on a rear side of the substrate, said rear side being situated opposite the substrate top side. The metallized circuit carrier or the metal layer can be embodied as an electrical contact pad for feeding back a current for a power electronic circuit.

This embodiment variant of the invention in the form of an electronic circuit device also enables the problem addressed by the invention to be solved rapidly and efficiently.

The approach presented here is explained in greater detail by way of example below with reference to the accompanying drawings, in which:

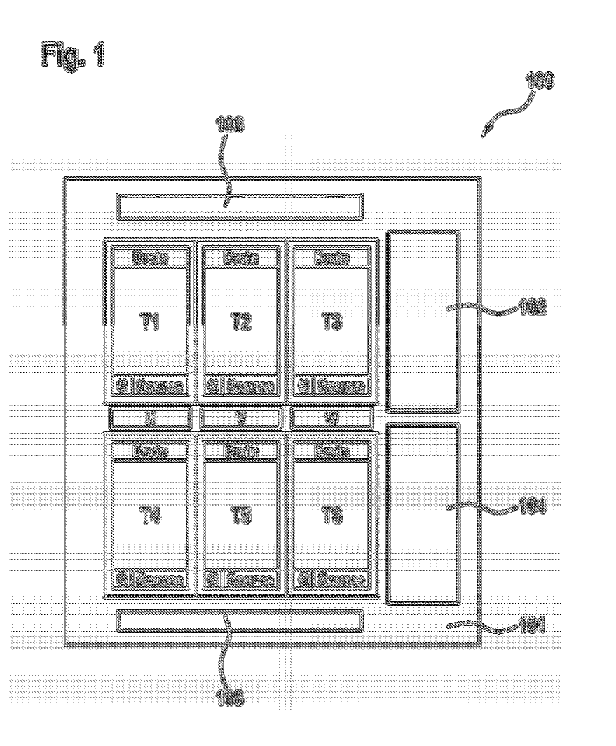

FIG. 1 shows a basic illustration of an electronic circuit;

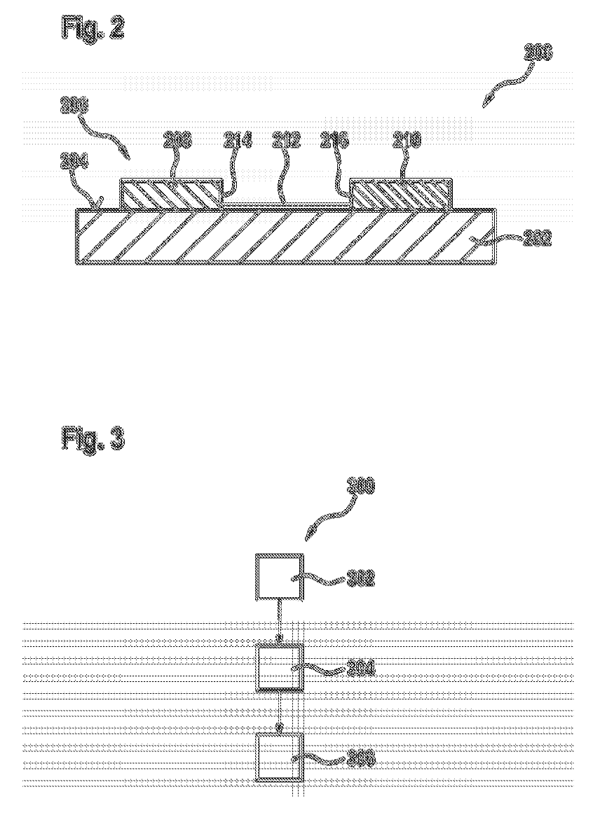

FIG. 2 shows a basic illustration of an electronic circuit device;

FIG. 3 shows a flow diagram of a method for producing an electronic circuit device in accordance with one exemplary embodiment of the present invention;

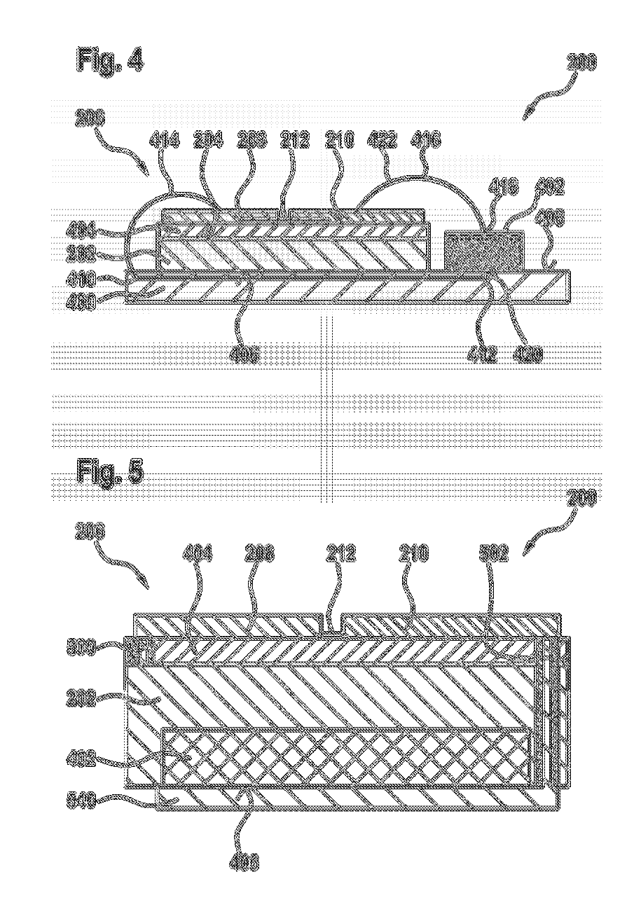

FIG. 4 shows a cross section of an electronic circuit device with a laterally arranged capacitor, in accordance with one exemplary embodiment of the present invention;

FIG. 5 shows a cross section of an electronic circuit device with a capacitor structured at the substrate rear side, in accordance with one exemplary embodiment of the present invention;

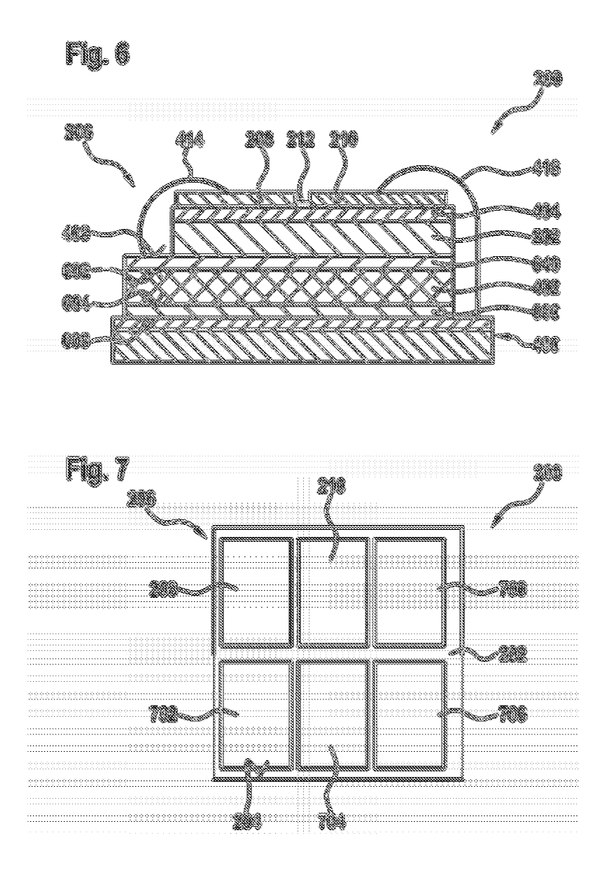

FIG. 6 shows a cross section of an electronic circuit device with heterogeneous integration of the capacitor by 3D stacking, in accordance with one exemplary embodiment of the present invention;

FIG. 7 shows a plan view of a front side of an electronic circuit device in accordance with one exemplary embodiment of the present invention;

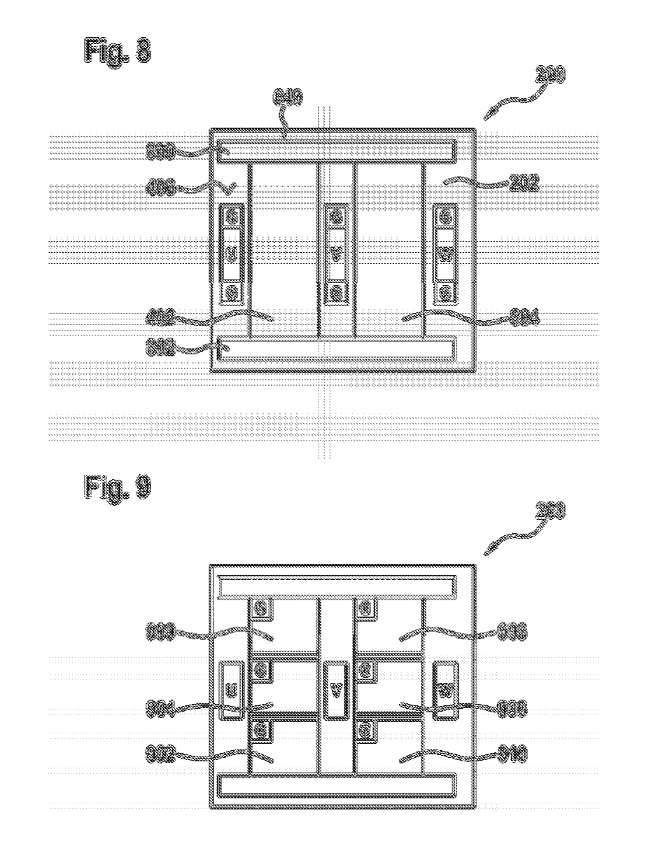

FIG. 8 shows a plan view of a rear side of an electronic circuit device in accordance with one exemplary embodiment of the present invention; and

FIG. 9 shows a plan view of a rear side of an electronic circuit device in accordance with a further exemplary embodiment of the present invention.

In the following description of expedient exemplary embodiments of the present invention, identical or similar reference signs are used for the similarly acting elements illustrated in the various figures, wherein a repeated description of said elements is dispensed with.

FIG. 1 shows a basic illustration of an electronic circuit 100 in accordance with the prior art. The circuit 100 is an inverter circuit comprising typically six active power switches or power transistors T1, T2, T3, T4, T5 and T6 on a circuit carrier 101. The power transistors T1, T2, T3, T4, T5 and T6 are constructed on the basis of GaN and/or AlGaN layers and are arranged as discrete components on the silicon substrate 101. Adjacent to the transistors T1, T2, T3, T4, T5 and T6, as passive components a capacitor 102 and driving electronics 104 and also terminals for supply voltage 106, ground 108 and loads U, V and W are arranged on the circuit carrier surface 101. Each transistors T1, T2, T3, T4, T5, T6 has three terminals: drain, gate G and source.

In the manufacture of the inverter circuit 100, the six power transistors T1, T2, T3, T4, T5, T6 were firstly singulated. Afterward, they were connected to the link capacitor 102, the driving or driver electronics 104, the gate driving electronics G and also the terminals for supply voltage 106, ground 108 and loads U, V, W. By virtue of the fact that the power transistors T1, T2, T3, T4, T5, T6 are lateral components, it is possible to connect a plurality of components already during processing at the wafer level. In contrast to the circuit shown here, consisting of discrete components at the wafer level, it is possible to interconnect the transistors T1, T2, T3, T4, T5 and T6 at the wafer level and to connect them to an integrated link capacitor 102 and the gate driving electronics G at the wafer level.

FIG. 2 shows a basic illustration of an electronic circuit device 200. The electronic circuit device 200 comprises a substrate 202 and a III-V compound semiconductor circuit 206 arranged on a substrate top side 204 of the substrate 202. The III-V compound semiconductor circuit 206 is composed of a first III-V compound semiconductor component 208, a second III-V compound semiconductor component 210 and an electrical conductor 212, which electrically conductively connects a terminal of the first III-V compound semiconductor component 208 to a terminal of the second III-V compound semiconductor component 210.

The substrate 202 is a silicon wafer in the exemplary embodiment shown.

The III-V compound semiconductor components 208, 210 are formed from materials of chemical main groups III (earth metals/boron group) and V (nitrogen-phosphorus group) or comprise materials of chemical main groups III and V. The electronic circuit device 200 can be used as part of power electronics in which the III-V compound semiconductor components 208, 210 form switching transistors, for example.

In accordance with one exemplary embodiment, the III-V compound semiconductor circuit 206 can comprise more than the two III-V compound semiconductor components 208, 210 shown, for example six III-V compound semiconductor components.

Furthermore, the III-V compound semiconductor circuit 206 can comprise more than the one electrical conductor 212 shown. By way of example, at least one further electrical conductor can be led between further terminals of the III-V compound semiconductor components 208, 210. Moreover, at least one further electrical conductor can be led between one of the III-V compound semiconductor components 208, 210 and a terminal contact of the III-V compound semiconductor circuit 206. In this case, the optional further conductors can be manufactured in a manner corresponding to the electrical conductor 212.

The elements 208, 210 of the III-V compound semiconductor circuit 206 were formed by chemical vapor deposition on the substrate surface 204. As shown by the illustration in FIG. 2, the electrical conductor 212 is applied to the substrate surface 204 such that it runs between a sidewall 214 of the first III-V compound semiconductor component 208 and a sidewall 216 of the second III-V compound semiconductor component 210. In this case, processing is carried out in the following order: firstly, a whole-area deposition of the III-V semiconductors is carried out. In this case, the III-V compound semiconductor components 208, 210 are deposited as a composite element. Afterward, a further processing is carried out in order to obtain two components. Two independent III-V compound semiconductor components 208, 210 are obtained as a result. Afterward, metalizing is carried out in order to connect the components at the correct location.

Consequently, the III-V compound semiconductor components 208, 210 are produced simultaneously during the processing and are thus initially not two components from geometric and chemical standpoints. They become two components only by means of a further processing. In accordance with one exemplary embodiment, the first and second III-V compound semiconductor components 208, 210 are situated on a III-V compound semiconductor layer and are intermeshed in one another. In addition, in a further embodiment, the conductor 212 can be positioned and structured on a III-V compound semiconductor material.

FIG. 3 shows a flow diagram of one exemplary embodiment of a method 300 for producing an electronic circuit device. The method 300 can be implemented for producing an electronic circuit device such as is shown in FIG. 2. A step of providing 302 involves providing a substrate. In a step 304, by depositing at least one first III-V compound semiconductor component, a second III-V compound semiconductor component and an electrical conductor, which electrically conductively connects the III-V compound semiconductor components, on a substrate surface of the substrate, a III-V compound semiconductor circuit is processed on the substrate. A step of arranging involves arranging a metallized circuit carrier or a metallization on a rear side of the substrate, said rear side being situated opposite the substrate top side. The metallized circuit carrier or the metallization provides an electrical contact pad for feeding back a current for a power electronic circuit.

In accordance with one exemplary embodiment of the method 300, in the step of processing 304, the III-V compound semiconductor components are applied to the substrate surface using a chemical vapor deposition method, in particular a metal-organic chemical vapor deposition method. The electrical conductor can be applied for example by means of thermal evaporation or physical deposition (sputtering).

FIG. 4 shows a variant of the electronic circuit device 200 presented herein in a cross-sectional illustration. The exemplary circuit device 200 shown in FIG. 4 comprises the silicon substrate 202 with the III-V compound semiconductor circuit 206 and also a metallized circuit carrier 400 and a passive circuit element 402—here a capacitor. The compound semiconductor circuit 206 once again comprises an exemplary first III-V compound semiconductor component 208, an exemplar second III-V compound semiconductor component 210 and also the electrical conductor 212, which electrically conductively connects the components 208, 210.

The exemplary electronic circuit device 200 shown in FIG. 4 is used as a commutation cell in which the III-V compound semiconductor circuit 206 forms a half-bridge circuit. Correspondingly, the first III-V compound semiconductor component 208 and the III-V compound semiconductor component 210 are embodied in each case as a GaN transistor, wherein the first GaN transistor 208 constitutes a switch and the second GaN transistor 210 constitutes a diode. The opposite situation can also prevail, depending on the circuit. Consequently, the first GaN transistor 208 can also constitute a diode and the second GaN transistor 210 can constitute a switch. An insulating buffer layer 404 is arranged between the III-V compound semiconductor circuit 206 and the substrate surface 204, said buffer layer extending over the entire substrate surface 204 in the exemplary embodiment shown.

The metallized circuit carrier 400 is arranged on a further substrate top side 406 of the substrate 202, said further substrate top side being situated opposite the substrate top side 204. In the exemplary embodiment shown in FIG. 4, the metallized circuit carrier 400 is embodied in a continuous fashion, completely covers the further substrate top side 406 and extends beyond the silicon substrate 202 on both sides.

By virtue of the larger dimensions of the circuit carrier 400 relative to the substrate 202, a surface 408 of the metallized circuit carrier 400 that adjoins the further substrate surface 406 offers a bearing area for the capacitor 402, for the lateral positioning of the capacitor 402 in relation to the construction comprising substrate 202 and III-V compound semiconductor circuit 206. The surface 408 of the metallized circuit carrier 400 forms an electrically conductive path with a first terminal 410 and a second terminal 412 for carrying the return current below the semiconductor components 208, 210.

For the power supply of the III-V compound semiconductor circuit 206, the first GaN transistor 208 is coupled to the first terminal 410 of the metallized circuit carrier 400 via a first bonding wire 414 and the second GaN transistor 210 is coupled to a terminal 418 of the passive circuit element 402 via a second bonding wire 416. The second terminal 412 of the metallized circuit carrier 400 is coupled to a further terminal 420 of the passive circuit element 402.

The parasitic inductance of the commutation cell 200 can be drastically reduced by the utilization of the substrate layer 202 for carrying the return current, as shown in the illustration in FIG. 4. In this case, the capacitor 402 required for the commutation processes is positioned alongside the semiconductor components 208, 210. The type of embodiment of the commutation capacitor 402 remains free in this case. In accordance with exemplary embodiments, further passive components can be structured on the rear side of the electronic circuit 200.

In accordance with exemplary embodiments, instead of the two transistors 208, 210 shown, the electronic circuit device 200 can also comprise the six transistors that are customary for an inverter circuit. Even further passive circuit elements can be provided besides the capacitor 402.

FIG. 5 shows a further exemplary embodiment of the electronic circuit device 200 once again in a cross-sectional illustration. Here, in contrast to the exemplary embodiment shown in FIG. 4, the passive circuit element 402 is not arranged adjacent to the III-V compound semiconductor circuit 206, but rather has been integrated on the rear side of the substrate on which the III-V compound semiconductor circuit is situated. Here the passive circuit element 402 is once against embodied as a capacitor. In the case of the exemplary embodiment shown in FIG. 5, the capacitor 402 is configured as a trench capacitor using trench technology.

As in the case of the exemplary embodiment shown in FIG. 4, the III-V compound semiconductor circuit 206 comprises the first GaN transistor 208 as a switch, the second GaN transistor 210 as a diode, and also the electrical conductor 212 connecting the semiconductor elements 208, 210.

With the monolithic integration of the passive circuit element 402 into the electronic circuit device 200 as shown in FIG. 5, it is possible to dispense with the bonding connections shown in FIG. 4. Instead, for the voltage supply of the III-V compound semiconductor circuit 206 at the wafer level a first through contact 500 is applied between the first III-V compound semiconductor component 208 and the trench capacitor 402 and a second through contact 502 is applied between the second III-V compound semiconductor component 210 and a metallization 540.

FIG. 6 shows a cross section of a further variant of the electronic circuit device 200 presented here. The stack comprising silicon substrate 202, buffer layer 404 and III-V compound semiconductor circuit 206 corresponds to the construction shown in FIGS. 4 and 5. As in the case of the exemplary embodiment shown In FIG. 5, the passive circuit element 402 is applied as a trench capacitor but, in contrast to the exemplary embodiment shown in FIG. 5, is not integrated into the silicon substrate 202, but rather below the substrate 202 between a metal layer 540 and the metallized circuit carrier 400. Specifically, the trench capacitor 402 is situated between a further top side 602 of the metal layer 640, said further top side being situated opposite the top side 408 of the metal layer 540, and a top side 604 of the metallized circuit carrier 400 facing the metal layer 540.

The heterogeneous integration of the passive circuit element 402 by 3D stacking as shown by way of example in FIG. 6 allows arbitrary extension of the electronic circuit device 200, here by an arrangement of a further circuit element 606 at an underside 608 of the circuit carrier 600, said underside being situated opposite the top side 604 of the circuit carrier 600. A substrate such as a cooler plate, for example, can be used as the further circuit element 606.

In the case of the exemplary embodiment of the electronic circuit device 200 as shown in. FIG. 6, the first bonding wire 414 electrically conductively connects the first III-V compound semiconductor component 208 to the metallization 400 and the second bonding wire 416 electrically conductively connects the second III-V compound semiconductor component 210 to the metallized circuit carrier 600.

In the case of the exemplary configuration of the electronic circuit device 200 as shown FIG. 6, the heterogeneous integration of the transistor substrate 402 with a capacitance based e.g. on Si technology is achieved e.g. by 3D stacking. In this configuration, the electrical connections 414, 416 between the semiconductor top side and the capacitor 402 can also be achieved by soldering as an alternative to the bonding shown in FIG. 6.

FIG. 7 schematically shows a plan view of a front side of one exemplar embodiment of the electronic circuit device 200. The illustration shows the circuit device 200 comprising the typical six transistors of the inverter circuit 206, alongside the transistors 208 and 210 four further transistors 700, 702, 704 and 706. In the case of the exemplary embodiment shown In FIG. 7 the transistors 208, 210, 700, 702, 704, 706 for the inverter circuit 206 were processed on the front side 204 of a silicon wafer 202 coated with GaN, AlN or AlGaN and were connected to the rear side via passage contacts (not shown).

FIG. 8 schematically shows a plan view of an exemplary rear side of the exemplary embodiment of the electronic circuit device 200 shown from the front or from above in FIG. 7. The illustration shows the further substrate top side 406 of the substrate 202 and the metal layer 640 arranged on said further substrate top side. In the case of the exemplary embodiment shown in FIG. 8, the metal layer 640 is structured, that is to say does not completely cover the further substrate top side 406.

Sections of the metallization 640 form a terminal for a supply voltage 800 in a first edge region, a ground terminal 802 in a second edge region situated opposite the first edge region, and terminals for loads U, V, N with assigned gate control terminals G between the edge regions. The capacitor 402 is situated as first passive circuit element between the load terminals U and V. A further capacitor 804 is situated as second passive circuit element between the load terminals V and W.

In the case of the exemplary embodiment shown in FIG. 8, the capacitors 402, 804 form link capacitors which are integrated into the substrate 202 monolithically on the rear side of the electronic circuit device 200 as trench capacitors at the wafer level and which are directly connected to the transistors (not shown here) at the wafer level. Furthermore, the rear side serves as contact area for supply voltage 800, ground 802, loads U, V, W and gate driving G. The loads U, V, W can be external conductors of an electric machine, for example of a three-phase machine. Consequently, the electronic circuit device 200 can constitute a control device for driving an electric machine.

The integration of the link capacitors 402, 804 in the case of the exemplary embodiment of the electronic circuit 200 shown in FIG. 8 enables a three-phase bridge circuit.

As a result of the integration of the link capacitors 402, 804 and of part of the gate driving electronics, as illustrated in FIG. 8, not only are soldering and bonding connections saved, at the same time the small distance affords the advantage that parasitic inductances are minimized. This minimization of the parasitic inductances allows the inverter circuit to be operated with higher switching frequencies, as a result of which the costs and the weight of the overall system can be reduced.

FIG. 9 shows a plan view of an alternative construction of the rear side of the electronic circuit device 200. The configuration of the exemplary circuit rear side shown in. FIG. 9 corresponds to that shown in FIG. 8, with the difference that a plurality of RC elements for damping, so-called RC snubbers, are used instead of the link capacitors.

Specifically, instead of the first capacitor, a first RC snubber 900, a second RC snubber 902 and a third RC snubber 904 are provided between the load terminals U and V and, instead of the second capacitor, a fourth. RC snubber 906, a fifth Rf snubber 908 and a sixth RC snubber 910 are provided between the load terminals V and W. Each of the RC snubbers 900, 902, 904, 906, 908, 910 has an arrangement for gate driving G and is assigned respectively to one of the transistors on the circuit front side.

In accordance with one exemplary embodiment, the RC snubbers 900, 902, 904, 906, 908, 910 can also be monolithically integrated in addition to the link capacitors on the rear side. Alternatively or additionally, other passive components can be monolithically integrated on the rear side.

FIGS. 8 and 9 show how the ESR (effective series resistance) can be designed in a targeted manner within the scope of the technological possibilities. As an alternative or in addition to the integration of the link capacitors 402, 804, it is possible to use the rear side of the wafer for further passive components. As depicted schematically in FIG. 9, there is e.g. the possibility of integrating RC elements 900, 902, 904, 906, 908, 910 for damping oscillations or further components for driving the gates, e.g. Si MOSFETs.

A main aspect of the circuit concept presented herein for integrated power electronics such as the inverter circuit consists in utilising the rear side of the silicon wafer 202 for carrying current and/or the monolithic or heterogeneous integration of passive components of the link capacitors 402, 804 and/or the electronics for gate driving G. In the production process, firstly the active components, e.g. in the case of the inverter the six transistors 208, 210, 700, 702, 704, 706 of a three-phase bridge circuit, are processed on the front side. Instead of singulating the transistors 208, 210, 700, 702, 704, 706, the electrical connections are led onto the rear side of the wafer 202 by means of e.g. through-plating.

With the aid of the concept presented herein, it is possible to increase the integration density of power semiconductor circuits on the basis of lateral switching, transistors. By means of monolithic or heterogeneous integration of passive components, such as e.g. the link capacitor on the rear side of the transistor substrate, the wafer front and rear sides can be utilized more optimally. Connections between the individual components are monolithically realized to the greatest possible extent at the wafer level. In addition, the distances between the active power transistors and the passive components are minimized and the parasitic impedances of the connection structures are reduced to a minimum.

On account of these optimizations, the dynamic component losses that occur during switching processes and also the EMC interference excitations can be considerably reduced. The utilization of the substrate for carrying current and the integration of passive components and driver structures give rise to new degrees of freedom in shielding and commutation-near filtering of the switching-dictated EMC interference.

The circuit concept presented herein can be taken as a basis for the production of power electronic circuits, e.g. for use in rotational speed-variable motor controllers, PFC circuits (PFC=Power Factor Correction) or DC/DC converters.

The exemplary embodiments described and shown in the figures have been chosen merely by way of example. Different exemplary embodiments can be combined with one another completely or with respect to individual features. Moreover, an exemplary embodiment can be supplemented by features of a further exemplary embodiment.

Furthermore, the method steps presented here can be implemented repeatedly and in a different order than that described.

If an exemplary embodiment comprises an “and/or” linkage between a first feature and a second feature, then this should be interpreted such that the exemplary embodiment comprises both the first feature and the second feature in accordance with one embodiment and comprises either only the first feature or only the second feature in accordance with a further embodiment.

1. A method for producing an electronic circuit device, comprising:
providing a substrate;
processing a III-V compound semiconductor circuit on a substrate top side of the substrate, the III-V compound semiconductor circuit including at least one first III-V compound semiconductor component, a second III-V compound semiconductor component, and an electrical conductor which electrically conductively connects the at least one first III-V compound semiconductor component and the second III-V compound semiconductor component; and
arranging a metal layer or a metallized circuit carrier on a rear side of the substrate, the rear side arranged opposite the substrate top side and configured as an electrical contact pad configured to feed back a current for a power electronic circuit.

2. The method as claimed in claim 1, wherein the processing of the III-V compound semiconductor circuit includes:
depositing, by way of whole area deposition, the III-V compound semiconductor components over whole area as a composite element;
processing the composite element so as to obtain the first III-V compound semiconductor component and the second III-V compound semiconductor component as two independent III-V compound semiconductor components; and
metalizing so as to produce the electrical conductor.

3. The method as claimed in claim 1, wherein the processing of the III-V compound semiconductor circuit includes:
processing the first III-V compound semiconductor component and the second III-V compound semiconductor component on a III-V compound semiconductor layer; and
intermeshing the first III-V compound semiconductor component and the second III-V compound semiconductor component in each other.

4. The method as claimed in claim 1, wherein the processing of the III-V compound semiconductor circuit includes:
positioning and structuring the electrical conductor on a III-V compound semiconductor material.

5. The method as claimed in claim 1, wherein the processing of the III-V compound semiconductor circuit includes:
producing the first III-V compound semiconductor component, the second III-V compound semiconductor component, and the electrical conductor using chemical vapor deposition.

6. The method as claimed in claim 1, wherein the processing of the III-V compound semiconductor circuit includes:
processing the III-V compound semiconductor circuit as a half or full bridge, as an inverter circuit or as a further power electronic circuit of including at least two elements.

7. The method as claimed in claim 1, wherein the processing of the III-V compound semiconductor circuit includes:
processing the first III-V compound semiconductor component as a switch of the III-V compound semiconductor circuit; and
processing the second III-V compound semiconductor component as a diode of the III-V compound semiconductor circuit.

8. The method as claimed in claim 1, further comprising:
providing a passive circuit element for the electronic circuit device; and
electrically conductively connecting a terminal of the passive circuit element to at least one of the first III-V compound semiconductor component and the second III-V compound semiconductor component.

9. The method as claimed in claim 1, wherein the providing of the passive circuit element includes:
producing the passive circuit element at the rear side of the substrate.

10. The method as claimed in claim 1, wherein the providing of the passive circuit element includes:
arranging the passive circuit element at a surface of the metallized circuit carrier facing away from rear side of the substrate.

11. The method as claimed in claim 1, wherein the providing of the passive circuit element includes:
structuring the passive circuit element in the rear side of the substrate.

12. The method as claimed in claim 1, wherein the providing of the substrate includes:
providing the substrate with at least one plated through hole configured to contact the III-V compound semiconductor circuit.

13. An electronic circuit device, comprising:
a substrate;
a III-V compound semiconductor circuit arranged on a substrate top side of the substrate, the III-V compound semiconductor circuit including:
at least one first III-V compound semiconductor component;
a second III-V compound semiconductor component; and
an electrical conductor which electrically conductively connects the first III-V compound semiconductor component and the second III-V compound semiconductor component.

14. The method as claimed in claim 5, further comprising:
producing the first III-V compound semiconductor component, the second III-V compound semiconductor component, and the electrical conductor using metal organic chemical vapor deposition.
